(19) United States
(12) Patent Application Publication
(10) Pub. No.: US 2001/0047820 A1
(43) Pub. Date: Dec. 6, 2001

(54) Solar powered IC mounted display

(76) Inventor: Barry M. Schneider, Manhasset, NY (US)

Correspondence Address: WILLIAM COLLARD, COLLARD & ROE, P.C., 1077 NORTHERN BOULEVARD, ROSLYN, NY, 11576, US

(21) Appl. No.: 09/751,954

(22) Filed: Dec. 29, 2000

Related U.S. Application Data
(60) Provisional application No. 60/175,002, filed on Jan. 7, 2000.

(51) Int. Cl. H02N 6/00; H01L 25/00; H01L 31/00; F21S 4/00

(52) U.S. Cl. 136/251; 136/244; 362/800

(57) ABSTRACT

The invention relates to a device that is designed as a solar powered integrated circuit. This solar powered integrated circuit contains a display, a solar cell and a non-volatile memory unit. The display displays a set of information stored in this non-volatile memory and is powered by the solar cell. This device can also contain an additional memory unit that can be in-circuit programmable. This device could also be powered by an additional power supply that powers the memory unit and the display when the solar cell does not produce enough energy to power the memory unit and the display. There is also a power control circuit that determines whether to use the solar cell or the additional power source based upon the level of the power output of the solar cell. Finally, the device can also contain a programming interface that could be either a serial interface or a parallel interface wherein this programming interface allows information to be imported into the device and stored in either the non-volatile memory unit or the additional memory unit.

This application is based upon provisional patent application Ser. No. 60/175,002 filed on Jan. 7, 2000.

### BACKGROUND OF THE INVENTION

1. Field of the Invention

The invention relates to an in system programmable (ISP) solid state non-volatile storage that is designed as an IC package mounted display with an on-board solar cell so that information fed into the storage can be displayed with or without external power.

2. The Prior Art

In the past, the method for identifying firmware versions has included stamping electrical assemblies with a code that represents the firmware version at some defined point in products development. However, in the past, these in-system programmable (ISP) devices caused configuration and control problems. For example, while these ISP devices allowed the modifications of the firmware after the electrical assembly was stamped, when the firmware was updated the stamp was incorrect. In addition, while there were ways to keep the markings up to date, these processes were expensive and were not automatic. In addition, the stamp needed to be readable when the assembly was in the un-powered state, allowing configuration to be known before the electronic device was operated. This result could only occur by re-stamping the assembly.

### SUMMARY OF THE INVENTION

Therefore to overcome the drawbacks of the prior art, the invention is designed to be a solar powered display mounted in either an integrated circuit or an interface board. This device contains a display, a solar cell and a non-volatile memory unit. The display displays a set of information stored in this non-volatile memory and is powered by the solar cell. This device can also contain an additional memory unit that can be in-circuit programmable. This device could also be powered by an additional power supply that powers the memory unit and the display when the solar cell does not produce enough energy to power the memory unit and the display. There is also a power control circuit that determines whether to use the solar cell or the additional power source based upon the level of the power output of the solar cell. Finally, the device can also contain a programming interface that could be either a serial interface or a parallel interface wherein this programming interface allows information to be imported into the device and stored in either the non-volatile memory unit or the additional memory unit.

The display could be in the form of a light-emitting-diode display (LED) or in the form of a liquid-crystal-display (LCD). The memory unit could be in the form of a flash memory unit or an electrically erasable programmable read only memory (EEPROM).

### BRIEF DESCRIPTION OF THE DRAWINGS

Other objects and features of the present invention will become apparent from the following detailed description considered in connection with the accompanying drawings, which disclose several embodiments of the present invention. It should be understood, however, that the drawings are designed for the purpose of illustration only and not as a definition of the limits of the invention.

In the drawings wherein similar reference characters denote similar elements throughout the several views:

FIG. 1 is a perspective view of a schematic diagram of the first embodiment of the invention;

FIG. 2 is perspective view of a second embodiment of the invention;

FIG. 3 is a block diagram of the electronic connection of the invention without the optional memory;

FIG. 4 is a block diagram of the electronic connection of the invention with the optional memory having a serial programming interface and a parallel operational interface; and

FIG. 5 is a block diagram of the electronic connection of the invention with the optional memory having a parallel interface.

### DETAILED DESCRIPTION OF THE PREFERRED EMBODIMENT

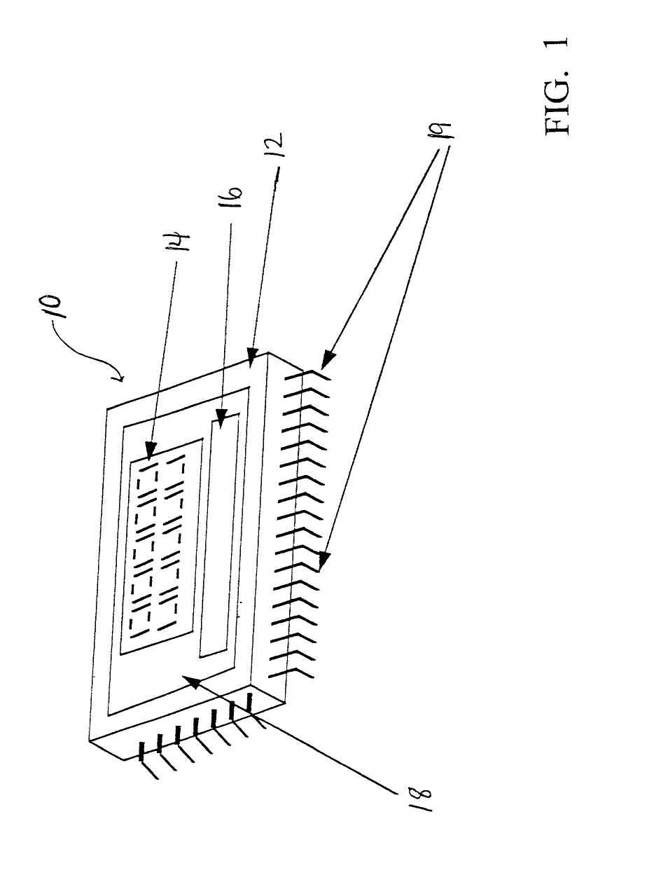

FIG. 1 refers to a perspective view of a schematic diagram of the invention. In this case, there is an IC display 10 formed by an IC package 12, a display 14, mounted on top of IC package 12, and a solar cell 16 that is also mounted on top of package 12. A window 18 covers the display 14 and solar cell 16 so that a viewer can still see display 14 and solar cell 16. In this case, there is also a plurality of IC pins 19 for attaching the IC package to a circuit board.

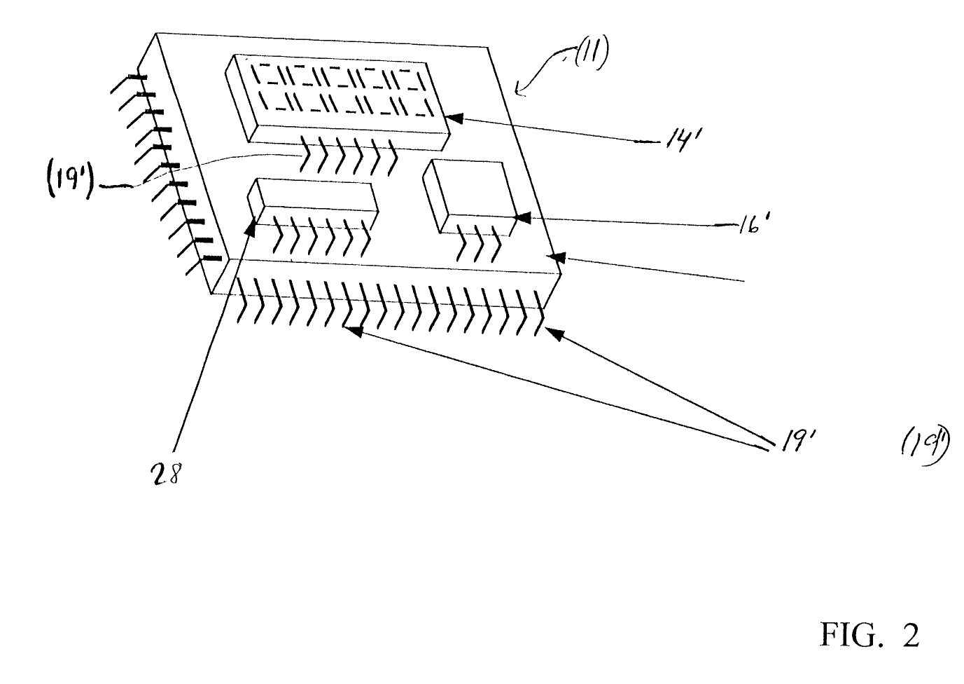

FIG. 2 shows another embodiment of the solar powered IC mounted display 10. In this case, the device is designed to fit on a small interface board 21 wherein there is a second embodiment of the solar cell 16′, and a second embodiment of the display 14′, wherein these components fit into the interface board 21 through a series of IC pins 19′. In addition, there are an additional series of IC pins 19″ attached to interface board 21 so that these pins 19″ are used to connect to another circuit board not shown.

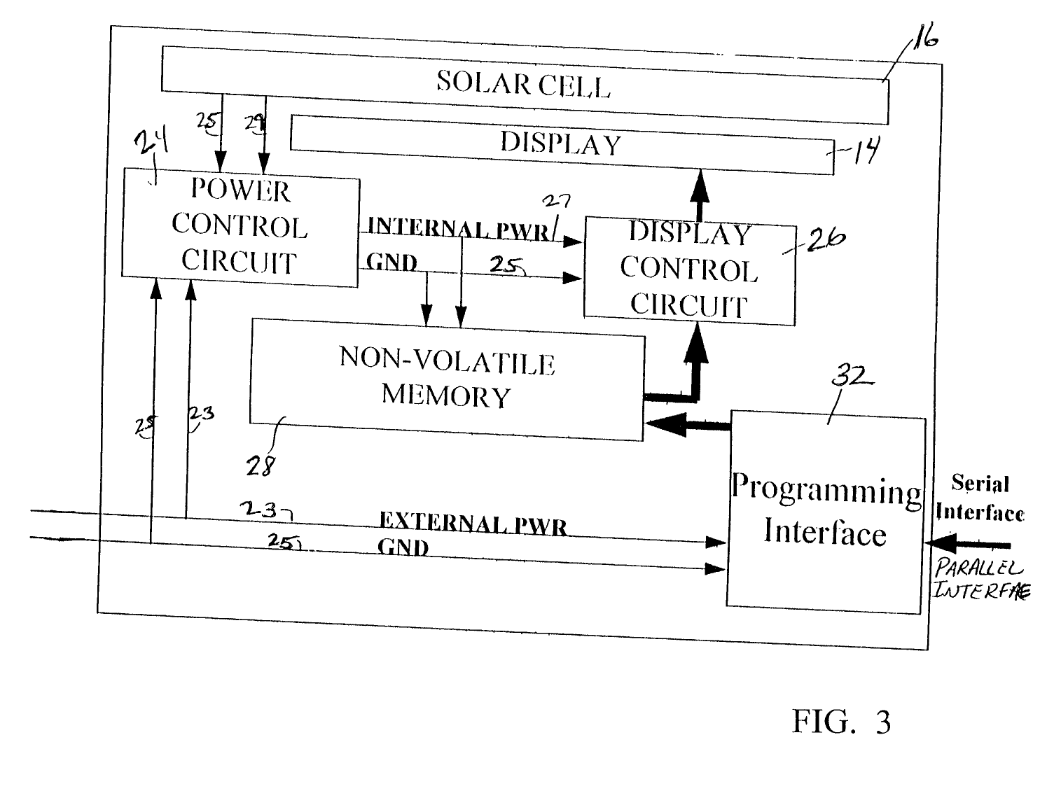

As shown in FIG. 3 there is a block diagram of the invention outlining the connection between solar cell 16, 16′, display 14 and 14′ and IC package 12. In this case, IC package 12 includes a power control circuit 24, a display control circuit 26, a non-volatile memory 28, and a programming interface 32.

Non-volatile memory 28 can come in the form of an electrical erasable programmable read only memory (EE PROM) that is grounded and connected to power control circuit 24, via ground line 25 and internal power line 27. Ground line 25 and internal power line 27 also connects power control circuit 24 to display control circuit 26. Power control circuit 24 also connects to ground line 25 and external power line 23 at one end to receive external power and solar cell power line 29 and ground line 23 at another end to receive solar power from solar cell 16.

Power control circuit 24 controls the power dispersed from the external power line 23 to non-volatile memory 28 and to display control circuit 26 so that when external power is fed to the circuit, power control circuit 24 allows power to flow into display control circuit 26 and onto display 14. However, if there is no external power being fed into power control circuit 24, then power control circuit 24 receives power from solar panel 16 via solar power line 29 and directs power to display control circuit 26 so that power is fed into display 14.

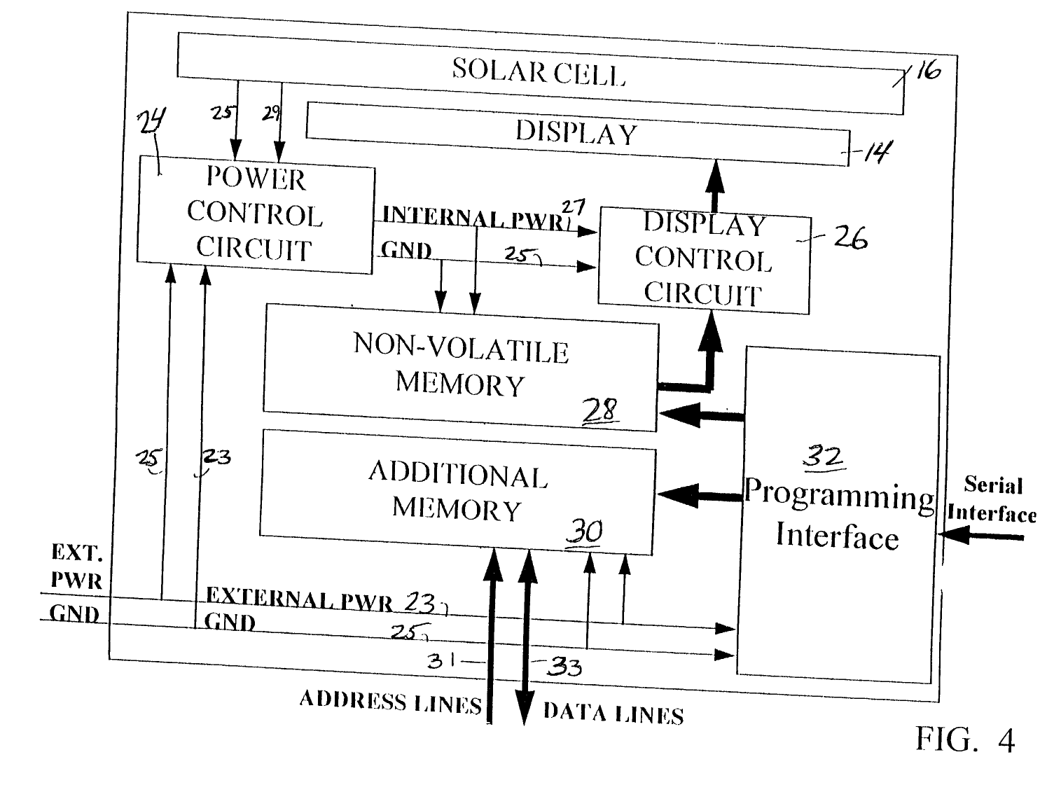

As shown in FIG. 4 an optional additional memory 30 could also be included wherein it is comprised of erasable electronic programmable read only memory or flash memory and can be used as a configuration memory for field programmable gate arrays. Optional additional memory 30 connects to programming interface 32 address lines 31 and 33 and to an external power source 23 and ground 25 for external power. FIG. 4 shows programming interface 32 having a serial interface that connects programming interface 32 to an external information source such as a personal computer or remote testing device.

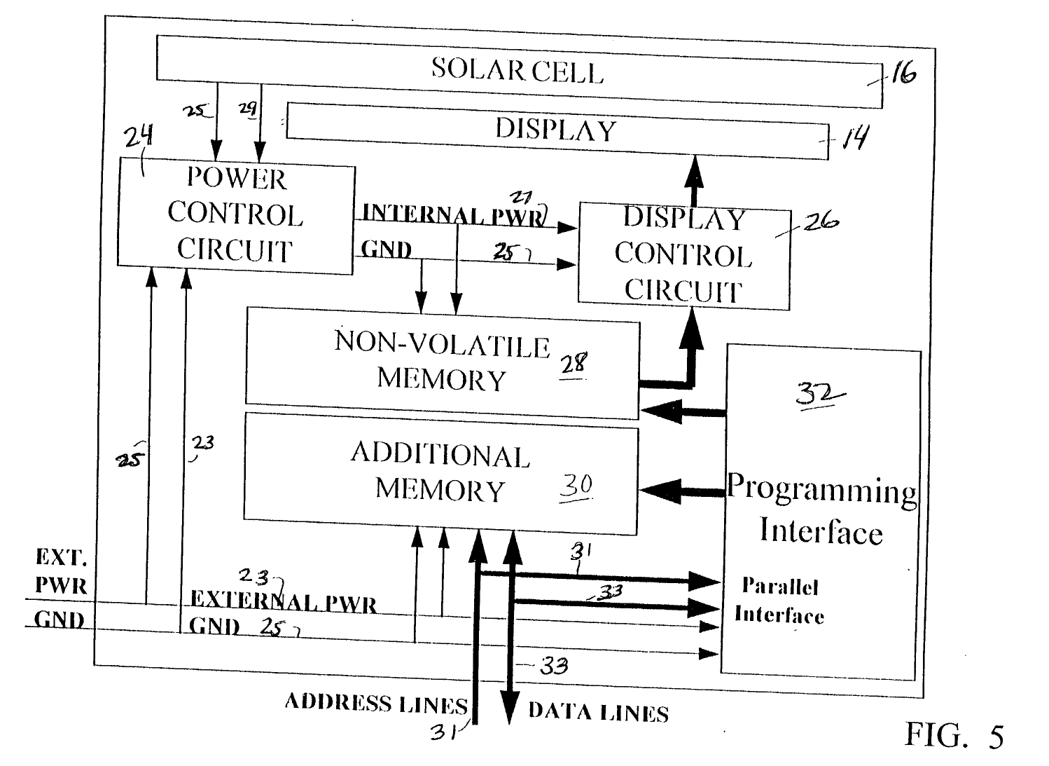

FIG. 5 differs from the embodiment shown in FIG. 4 in that programming interface 32 has a parallel connection to address lines 31 and data lines 33 that also connect to additional memory 30.

Thus, this solar powered IC mounted display can be connected to a serial or parallel port to a PC or other programming device so as to program non-volatile memory 28 and optional additional memory 30 through programming interface 32. In this way, if the additional memory were programmed to contain a software update the non-volatile memory 28 could store the revision number of that update and print it out onto display 14. Therefore, if a particular software program were revised so that there was a second version of that software program then display 14 would state rev 2 as the revision number.

In operation, non-volatile memory 28 can be written by a microprocessor with run time system status. This status may contain system failure statements or modes of a system before it is powered off. This device will enable the operator to read this system status without applying power.

In addition, additional memory 30 could be in-circuit programmable. In this case, the file is formatted so that the code revision value will be written into the memory location powered by the solar cell. The contents of this location will be displayed on the display even when there is no system power.

The device may be used for real time status when there is an external power source applied. In this mode, the device will display characters or graphics based upon the input conditions. When the external power is off, the device may display the contents of the non-volatile memory on the display. The data may be firmware version or other configuration information.

In addition, the device may be used as an elapsed time meter so that system time may be written into the device at run time and stored in the non-volatile memory. This elapsed time may be viewed at any time the device is illuminated.

Furthermore, this device will display stored data from an internal non-volatile memory. The data could have been written in circuit, in-system programmed or pre-programmed before installation into the next higher assembly. The source of the data may be the result of a real time process when the system is energized.

To switch from viewing the revision number on the display to the elapsed time meter, a user could repeatedly flash a light on solar cell 16 or 16′ so as to scroll through the possible information views on display 14. With this feature, there could be many different read outs for a single display and thus, memory 28 could store multiple different views for a person reading display 14.

Accordingly, while a few embodiments of the present invention have been shown and described, it is to be understood that many changes and modifications may be made thereunto without departing from the spirit and scope of the invention.

What is claimed is:

1. A solar powered device comprising:
a) a housing;
b) at least one solar cell disposed within said housing;
c) at least one display disposed within said housing and electrically connected to said solar cell; and
d) at least one memory unit disposed within said housing and electrically connected to said solar cell said at least one memory unit being in communication with said at least one display wherein said at least one display displays a set of information stored in said at least one memory unit.

2. The device as in claim 1, wherein said at least one display is a light emitting diode.

3. The device as in claim 1, wherein said at least one display is a liquid crystal display.

4. The device as in claim 1, further comprising at least one light disposed within said housing for lighting said display.

5. The device as in claim 1, wherein said at least one memory unit is in the form of a non-volatile memory.

6. The device as in claim 1, wherein said at least one memory unit is in the form of an in-circuit programmable memory.

7. The device as in claim 6, wherein said at least one memory unit is designed as an electrical erasable programmable read only memory (EEPROM)

8. The device as in claim 6, wherein said at least one memory unit is designed as a flash memory unit.

9. The device as in claim 1, further comprising at least one additional memory unit disposed within said housing and coupled to said at least one memory unit.

10. The device as in claim 1, further comprising at least one processor disposed within said housing and coupled to said solar cell and said at least one memory unit.

11. The device as in claim 10, wherein said at least one processor is designed to process and write said set of information to said at least one memory unit.

12. The device as in claim 1, further comprising an interface board for connecting said at least one memory unit, said at least one display and said at least one solar cell together to create a single interconnected unit.

13. The device as in claim 1, wherein said at least one memory unit, said at least one display and said at least one solar cell are combined together on an integrated circuit to create a single interconnected unit.

14. The device as in claim 1, further comprising at least one additional power source coupled to said display and said at least one memory unit.

15. The device as in claim 14, wherein said at least one additional power source is in the form of an internal power source disposed within said housing.

16. The device as in claim 14, wherein said at least one additional power source is in the form of an external power source which electrically connects to said memory unit, and said display.

17. The device as in claim 14, further comprising at least one power control circuit for determining the source of, and controlling the flow of power into said at least one display and said at least one memory unit.

17. The device as in claim 14, wherein said at least one power control circuit determines whether to draw power from said solar cell or from said at least one additional power source.

18. The device as in claim 17, wherein said at least one power control circuit determines whether to draw power from said at least one solar cell, or from said at least one additional power source by determining whether the minimum power output by said at least one solar cell is sufficient to display said set of information on said at least one display.

19. The device as in claim 1, further comprising at least one program input interface, wherein said at least one programming interface is disposed within said housing and is coupled to said at least one memory.

20. The device as in claim 19, wherein said program input interface is designed as a serial interface for connecting with a computer.

21. The device as in claim 19, wherein said program input interface is designed as a parallel interface for connecting with a computer.
